(19) United States
(12) Patent Application Publication
(10) Pub. No.: US 2026/0082556 A1
(43) Pub. Date: Mar. 19, 2026

(54) SEMICONDUCTOR DEVICE

(71) Applicant: Kioxia Corporation, Tokyo (JP)

(72) Inventors: Wataru HASEGAWA, Yokkaichi (JP); Takuya KONNO, Yokkaichi (JP)

(73) Assignee: Kioxia Corporation, Tokyo (JP)

(21) Appl. No.: 19/044,910

(22) Filed: Feb. 4, 2025

(30) Foreign Application Priority Data
Sep. 18, 2024 (JP) 2024-161473

(51) Int. Cl. H10B 43/20; H01L 25/18; H10B 43/10; H10B 43/35; H10B 80/00

(52) U.S. Cl. CPC H10B 43/20; H10B 43/10; H10B 43/35; H10B 80/00; H10W 90/00

(57) ABSTRACT

In one embodiment, a semiconductor device includes a stacked film alternately including first insulators and electrode layers in a first direction, and including a non-staircase portion, and a staircase portion provided in a second direction relative to the non-staircase portion. The device further includes a first pillar portion including a second insulator provided in the staircase portion. The stacked film includes partial stacked films stacked in the first direction, and the first pillar portion includes partial pillar portions respectively provided in the partial stacked films. The partial pillar portions include a first partial pillar portion having a first major radius and a first minor radius, and a second partial pillar portion having a second major radius and a second minor radius, an angle of the first/second major radius relative to the second direction being smaller/larger than an angle of the first/second minor radius relative to the second direction.

### CROSS REFERENCE TO RELATED APPLICATION

This application is based upon and claims the benefit of priority from the prior Japanese Patent Application No. 2024-161473, filed on Sep. 18, 2024, the entire contents of which are incorporated herein by reference.

### FIELD

Embodiments described herein relate to a semiconductor device.

### BACKGROUND

In general, a three-dimensional semiconductor memory includes a stacked film that alternately includes a plurality of insulators and a plurality of electrode layers (e.g., word lines) in the vertical direction. When manufacturing such a three-dimensional semiconductor memory, it is common to form a plurality of slits in the stacked film to divide the stacked film into a plurality of plate portions (finger portions). In this case, the plate portions may tilt or collapse due to, for example, staircase portions in the stacked film.

### BRIEF DESCRIPTION OF THE DRAWINGS

FIG. 1 is a cross-sectional view illustrating the structure of a semiconductor device of a first embodiment;

FIG. 2 is an enlarged cross-sectional view illustrating the structure of the semiconductor device of the first embodiment;

FIG. 3 is another cross-sectional view illustrating the structure of the semiconductor device of the first embodiment;

FIG. 4 is another cross-sectional view illustrating the structure of the semiconductor device of the first embodiment;

FIG. 5 is another cross-sectional view illustrating the structure of the semiconductor device of the first embodiment;

FIG. 6 is another cross-sectional view illustrating the structure of the semiconductor device of the first embodiment;

FIGS. 7A to 7C are plan views illustrating the structure of a semiconductor device of a comparative example of the first embodiment;

FIGS. 8A to 8C are plan views illustrating the structure of the semiconductor device of the first embodiment;

FIG. 9 is a plan view illustrating Examples 1 to 8 of the structure of the semiconductor device of the first embodiment;

FIGS. 10A to 10C are cross-sectional views illustrating the structure of a semiconductor device of a first modification of the first embodiment;

FIGS. 11A to 11C are cross-sectional views illustrating the structure of a semiconductor device of a second modification of the first embodiment;

FIGS. 12A to 12C are cross-sectional views illustrating the structure of a semiconductor device of a third modification of the first embodiment;

FIG. 13 is a cross-sectional view illustrating the structure of a semiconductor device of a second embodiment;

FIG. 14 is a plan view illustrating the structure of the semiconductor device of the second embodiment;

FIGS. 15A to 15C are plan views illustrating the structure of the semiconductor device of the second embodiment;

FIG. 16 is a cross-sectional view illustrating the structure of a semiconductor device of a third embodiment; and

FIGS. 17 and 18 are cross-sectional views illustrating a method of manufacturing the semiconductor device of the third embodiment.

### DETAILED DESCRIPTION

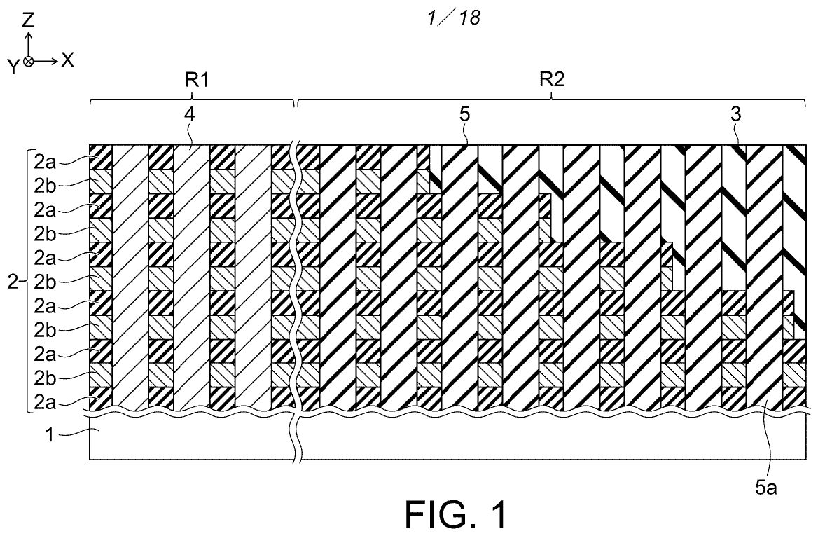

Embodiments will now be explained with reference to the accompanying drawings. The same components in FIGS. 1 to 18 are denoted by the same reference sign, and duplicate description of components is omitted.

In one embodiment, a semiconductor device includes a stacked film alternately including a plurality of first insulators and a plurality of electrode layers in a first direction, and including a non-staircase portion, and a staircase portion that is provided in a second direction relative to the non-staircase portion. The device further includes a first columnar portion including a charge storage layer and a semiconductor layer that are provided in the non-staircase portion. The device further includes a first pillar portion including a second insulator that is provided in the staircase portion. The stacked film includes a plurality of partial stacked films that are stacked in the first direction, and the first pillar portion includes a plurality of partial pillar portions that are respectively provided in the plurality of partial stacked films. The plurality of partial pillar portions in the first pillar portion include one or more first partial pillar portions each having a first major radius and a first minor radius in a plan view, an angle of the first major radius relative to the second direction being smaller than an angle of the first minor radius relative to the second direction, and one or more second partial pillar portions each having a second major radius and a second minor radius in a plan view, an angle of the second major radius relative to the second direction being larger than an angle of the second minor radius relative to the second direction.

### First Embodiment

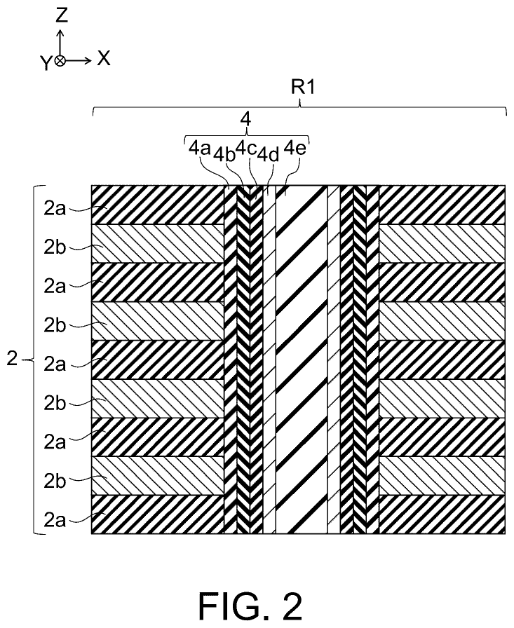

FIG. 1 is a cross-sectional view illustrating the structure of a semiconductor device of a first embodiment. FIG. 2 is an enlarged cross-sectional view illustrating the structure of the semiconductor device of the first embodiment.

The semiconductor device of the present embodiment is, for example, a three-dimensional semiconductor memory. Hereinafter, the structure of the semiconductor device of the present embodiment will be described mainly with reference to FIG. 1. FIG. 2 is also referred as appropriate in the description.

The semiconductor device of the present embodiment includes a substrate 1, a stacked film 2, an inter layer dielectric 3, a plurality of columnar portions 4, and a plurality of pillar portions 5. The stacked film 2 includes a plurality of insulators 2a and a plurality of electrode layers 2b. Each columnar portion 4 includes a block insulator 4a, a charge storage layer 4b, a tunnel insulator 4c, a channel semiconductor layer 4d, and a core insulator 4e (FIG. 2). Each pillar portion 5 includes an insulator 5a. Each columnar portion 4 is an example of the first columnar portion, and each pillar portion 5 is an example of the first pillar portion or a second pillar portion. Each insulator 2a in the stacked film 2 is an example of a first insulator, and the insulator 5a in each pillar portion 5 is an example of a second insulator. The channel semiconductor layer 4d is an example of a semiconductor layer.

The substrate 1 is, for example, a semiconductor substrate such as a silicon (Si) substrate. FIG. 1 illustrates an X direction and a Y direction that are parallel to the surface of the substrate 1 and orthogonal to each other, and a Z direction orthogonal to the surface of the substrate 1. In the present specification, the +Z direction is an upward direction, and the -Z direction is a downward direction. The −Z direction may or may not be aligned with the direction of gravity. The Z direction is an example of a first direction, the X direction is an example of a second direction, and the Y direction is an example of a third direction.

The stacked film 2 is formed on the substrate 1 and alternately includes the plurality of insulators 2a and the plurality of electrode layers 2b in the Z direction. Each insulator 2a is, for example, a silicon oxide film (SiO₂ film). Each electrode layer 2b includes, for example, a metal layer such as a tungsten (W) layer. Each electrode layer 2b of the present embodiment functions as a word line or a selection line of the three-dimensional semiconductor memory. The stacked film 2 may be formed directly on the substrate 1 or may be formed on the substrate 1 with another film in between.

The stacked film 2 includes a non-staircase portion (flat portion) R1 and a staircase portion R2. The non-staircase portion R1 has an upper face with a non-staircase shape (flat shape). The staircase portion R2 has an upper face and a side face each with a staircase shape. In FIG. 1, the staircase portion R2 is formed in the X direction relative to the non-staircase portion R1. Further details of the stacked film 2 will be described later.

The inter layer dielectric 3 is formed on the staircase portion R2 to eliminate a step between the upper face of the non-staircase portion R1 and the upper face of the staircase portion R2. The inter layer dielectric 3 is, for example, a tetraethyl orthosilicate (TEOS) film or an SiO₂ film.

As illustrated in FIG. 1, each columnar portion 4 is formed in the staircase portion R2, has a columnar shape extending in the Z direction, and penetrates through the stacked film 2 in the Z direction. As illustrated in FIG. 2, each columnar portion 4 includes the block insulator 4a, the charge storage layer 4b, the tunnel insulator 4c, the channel semiconductor layer 4d, and the core insulator 4e sequentially formed on a side face of the stacked film 2. The block insulator 4a is, for example, an SiO₂ film. The charge storage layer 4b is, for example, a silicon nitride film (SiN film). The charge storage layer 4b of the present embodiment can store signal electric charge of the three-dimensional semiconductor memory. The tunnel insulator 4c is, for example, an SiO₂ film. The channel semiconductor layer 4d is, for example, a polysilicon layer. The channel semiconductor layer 4d of the present embodiment functions as channels of a plurality of cell transistors (memory cells) and a plurality of selection transistors in the three-dimensional semiconductor memory. The core insulator 4e is, for example, an SiO₂ film. Further details of each columnar portion 4 will be described later.

As illustrated in FIG. 1, each pillar portion 5 is formed in the staircase portion R2 (or in the inter layer dielectric 3 and the staircase portion R2), has a columnar shape extending in the Z direction, similarly to each columnar portion 4, and penetrates through the stacked film 2 (or the inter layer dielectric 3 and the stacked film 2) in the Z direction. As illustrated in FIG. 1, each pillar portion 5 includes the insulator 5a. The insulator 5a is, for example, an SiO₂ film. Each pillar portion 5 of the present embodiment functions as a pillar that suppresses collapse of the stacked film 2 in a replacement process or the like. Further details of each pillar portion 5 will be described later.

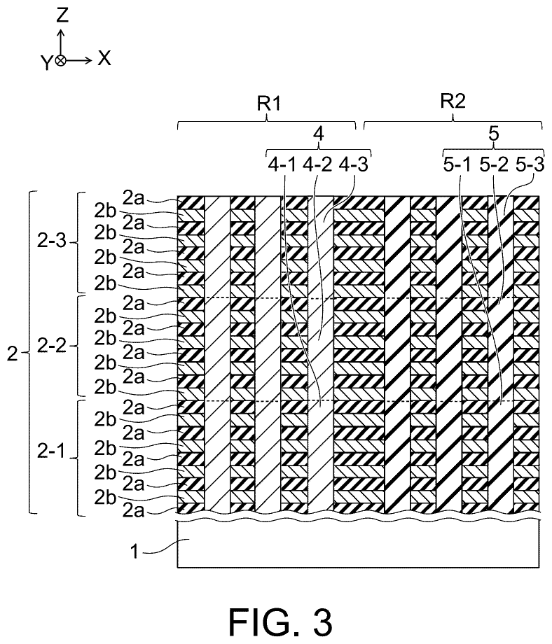

FIG. 3 is another cross-sectional view illustrating the structure of the semiconductor device of the first embodiment.

FIG. 3 illustrates details of the stacked film 2, the plurality of columnar portions 4, and the plurality of pillar portions 5 illustrated in FIG. 1. The stacked film 2 includes a lower partial stacked film 2-1, an intermediate stacked film 2-2, and an upper partial stacked film 2-3 sequentially stacked in the Z direction. Each columnar portion 4 includes a lower columnar portion 4-1, an intermediate columnar portion 4-2, and an upper columnar portion 4-3 sequentially provided in the Z direction. Each pillar portion 5 includes a lower partial pillar portion 5-1, an intermediate pillar portion 5-2, and an upper partial pillar portion 5-3 sequentially provided in the Z direction. The lower partial stacked film 2-1, the intermediate stacked film 2-2, and the upper partial stacked film 2-3 in the stacked film 2 are an example of a plurality of partial stacked films. The lower partial pillar portion 5-1, the intermediate pillar portion 5-2, and the upper partial pillar portion 5-3 in each pillar portion 5 are an example of a plurality of partial pillar portions.

Each of the lower partial stacked film 2-1, the intermediate stacked film 2-2, and the upper partial stacked film 2-3 alternately includes a plurality of insulators 2a and a plurality of electrode layers 2b in the Z direction. In the present embodiment, the lower partial stacked film 2-1 is the lowest stacked film among the lower partial stacked film 2-1, the intermediate stacked film 2-2, and the upper partial stacked film 2-3, and the upper partial stacked film 2-3 is the highest stacked film among the lower partial stacked film 2-1, the intermediate stacked film 2-2, and the upper partial stacked film 2-3. The intermediate stacked film 2-2 is a stacked film other than the lowest and highest stacked films among the lower partial stacked film 2-1, the intermediate stacked film 2-2, and the upper partial stacked film 2-3.

The lower columnar portion 4-1, the intermediate columnar portion 4-2, and the upper columnar portion 4-3 in each columnar portion 4 are formed in the lower partial stacked film 2-1, the intermediate stacked film 2-2, and the upper partial stacked film 2-3, respectively. Similarly to the stacked film 2, the lower columnar portion 4-1, the intermediate columnar portion 4-2, and the upper columnar portion 4-3 in each columnar portion 4 are the lowest columnar portion, the highest columnar portion, and a columnar portion other than the lowest and highest columnar portions, respectively.

The lower partial pillar portion 5-1, the intermediate pillar portion 5-2, and the upper partial pillar portion 5-3 in each pillar portion 5 are formed in the lower partial stacked film 2-1, the intermediate stacked film 2-2, and the upper partial stacked film 2-3, respectively. Similarly to the stacked film 2, the lower partial pillar portion 5-1, the intermediate pillar portion 5-2, and the upper partial pillar portion 5-3 in each pillar portion 5 are the lowest pillar portion, the highest pillar portion, and a pillar portion other than the lowest and highest pillar portions, respectively. Further details of each pillar portion 5 will be described later.

As described above, the staircase portion R2 has an upper face and a side face with a staircase shape (refer to FIG. 1). FIG. 3 omits illustration of such a staircase shape. In the present embodiment, such a staircase shape is formed in the lower partial stacked film 2-1, the intermediate stacked film 2-2, and the upper partial stacked film 2-3 in the staircase portion R2.

The stacked film 2, the plurality of columnar portions 4, and the plurality of pillar portions 5 illustrated in FIG. 3 are formed as follows, for example. First, the lower partial stacked film 2-1 is formed on the substrate 1, and a plurality of lower memory holes and a plurality of lower holes are formed in the lower partial stacked film 2-1. Subsequently, the intermediate stacked film 2-2 is formed on the lower partial stacked film 2-1, and a plurality of intermediate memory holes and a plurality of intermediate holes are formed in the intermediate stacked film 2-2. Subsequently, the upper partial stacked film 2-3 is formed on the intermediate stacked film 2-2, and a plurality of upper memory holes and a plurality of upper holes are formed in the upper partial stacked film 2-3. Subsequently, each pillar portion 5 is formed in one hole including a lower hole, an intermediate hole, and an upper hole, and each columnar portion 4 is formed in one memory hole including a lower memory hole, an intermediate memory hole, and an upper memory hole. Subsequently, slits are formed in the stacked film 2, a plurality of sacrifice layers in the stacked film 2 are replaced with the plurality of electrode layers 2b by using these slits (replacement process), and a plurality of insulators 6 (to be described later) are formed in the slits. In this manner, the semiconductor device illustrated in FIG. 3 is manufactured. Note that when the stacked film 2 is formed, each of the lower partial stacked film 2-1, the intermediate stacked film 2-2, and the upper partial stacked film 2-3 is formed to alternately include a plurality of insulators 2a and a plurality of sacrifice layers in the Z direction.

Note that the stacked film 2 may include two or more intermediate stacked films 2-2 between the lower partial stacked film 2-1 and the upper partial stacked film 2-3. In other words, the stacked film 2 may include four or more stacked films (one lower partial stacked film 2-1, two or more intermediate stacked films 2-2, and one upper partial stacked film 2-3).

Alternatively, the stacked film 2 may include no intermediate stacked film 2-2 between the lower partial stacked film 2-1 and the upper partial stacked film 2-3. In other words, the stacked film 2 may include only two stacked films (one lower partial stacked film 2-1 and one upper partial stacked film 2-3).

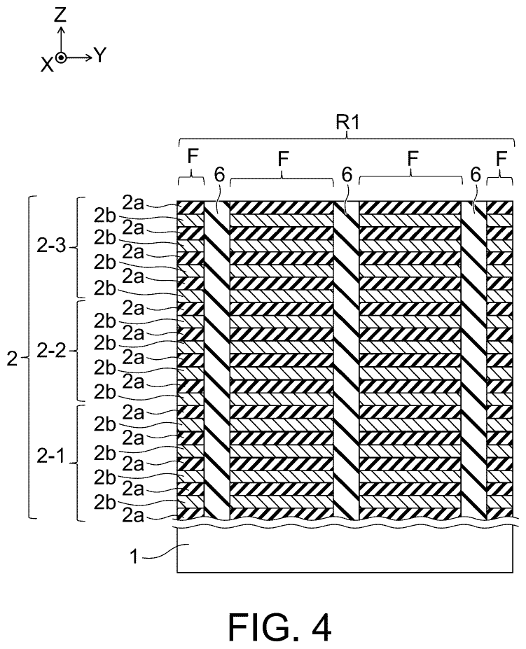

FIG. 4 is another cross-sectional view illustrating the structure of the semiconductor device of the first embodiment.

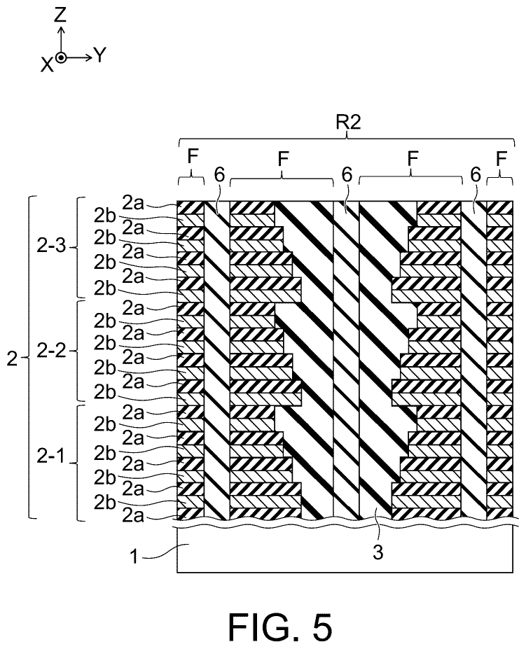

Although FIGS. 1 to 3 illustrate an XZ section of the semiconductor device of the present embodiment, FIG. 4 illustrates a YZ section of the semiconductor device of the present embodiment. Specifically, FIG. 4 illustrates a YZ section of the non-staircase portion R1 but omits illustration of the columnar portions 4 in the non-staircase portion R1. Similarly, FIG. 5 to be described later illustrates a YZ section of the staircase portion R2 but omits illustration of the pillar portions 5 in the staircase portion R2.

FIG. 4 illustrates a plurality of finger portions (plate portions) F formed in the stacked film 2. The finger portions F have plate shapes extending in the Z and X directions and are adjacent to each other in the Y direction. As described later, the finger portions F are continuously formed in the non-staircase portion R1 and the staircase portion R2 (refer to FIGS. 4 and 5). In the present embodiment, the plurality of columnar portions 4 (not illustrated in FIG. 4) are provided in a non-staircase portion F1 of each finger portion F, and the plurality of pillar portions 5 (not illustrated in FIG. 5) are provided in a staircase portion F2 of each finger portion F. Each finger portion F is an example of a first plate portion.

The semiconductor device of the present embodiment further includes the plurality of insulators 6. The insulators 6 have plate shapes extending in the Z and X directions and are adjacent to each other in the Y direction. The insulators 6 penetrate through the stacked film 2 in the Z direction and are continuously formed in the non-staircase portion R1 and the staircase portion R2. The stacked film 2 of the present embodiment is divided into the above-described plurality of finger portions F by the insulators 6. The insulators 6 are alternately provided with the above-described plurality of finger portions F in the Y direction. Each insulator 6 is, for example, an SiO₂ film. Each insulator 6 is an example of a second plate portion. Note that the second plate portion may include the insulator 6 and a semiconductor layer or metal layer embedded in the insulator 6.

FIG. 5 is another cross-sectional view illustrating the structure of the semiconductor device of the first embodiment.

FIG. 5 illustrates a YZ section of the semiconductor device of the present embodiment. Specifically, FIG. 5 illustrates a YZ section of the staircase portion R2 but omits illustration of the pillar portions 5 in the staircase portion R2.

As described above, the plurality of finger portions F and the plurality of insulators 6 illustrated in FIG. 5 are the same as the plurality of finger portions F and the plurality of insulators 6 illustrated in FIG. 4. The finger portions F and the insulators 6 are continuously formed in the non-staircase portion R1 and the staircase portion R2.

The staircase portion R2 has an upper face and a side face with a staircase shape (refer to FIG. 1). The upper face and the side face form a staircase descending in the +X direction in FIG. 1. The staircase portion R2 of the present embodiment further has a staircase shape on a side face of each finger portion F in the +Y direction or the −Y direction (FIG. 5). FIG. 5 exemplarily illustrates staircases of two of four finger portions F. In the present embodiment, each of the lower partial stacked film 2-1, the intermediate stacked film 2-2, and the upper partial stacked film 2-3 in each finger portion F includes a staircase descending in the +Y direction or the −Y direction (FIG. 5). In FIG. 5, one finger portion F includes a staircase descending in the +Y direction on a side face in the +Y direction, and another finger portion F includes a staircase descending in the −Y direction on a side face in the −Y direction.

In FIG. 5, one finger portion F including a staircase is adjacent to one insulator 6 on the staircase side with a gap between the finger portion F and the insulator 6. In FIG. 5, the above-described inter layer dielectric 3 is formed in the gap. This is because the insulators 6 of the present embodiment are formed in the stacked film 2 and the inter layer dielectric 3 after the staircase portion R2 and the inter layer dielectric 3 are formed.

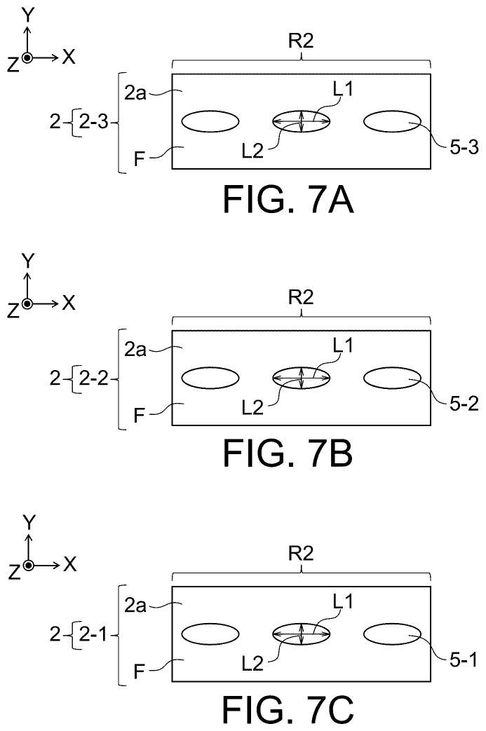

In the present embodiment, the finger portions F tilt or collapse due to the staircase portion R2 in the stacked film 2 or the like in some cases. For example, each finger portion F of the present embodiment has a shape that is mirror-asymmetric in the Y direction because of the staircases illustrated in FIG. 5. Accordingly, each finger portion F tilts or collapses in the Y direction due to the mirror asymmetry in some cases. A method of preventing such tilt and collapse will be described below with reference to FIGS. 7A to 12C.

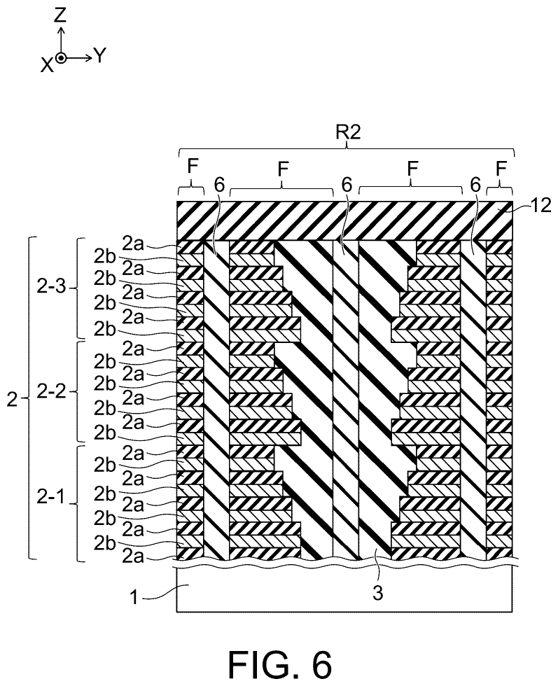

FIG. 6 is another cross-sectional view illustrating the structure of the semiconductor device of the first embodiment.

Similarly to FIG. 5, FIG. 6 illustrates a YZ section of the semiconductor device of the present embodiment. As illustrated in FIG. 6, the semiconductor device of the present embodiment includes an inter layer dielectric 12 formed on the stacked film 2, the inter layer dielectric 3, and the plurality of insulators 6. The inter layer dielectric 12 is, for example, a TEOS film or an SiO₂ film.

FIGS. 7A to 7C are plan views illustrating the structure of a semiconductor device of a comparative example of the first embodiment.

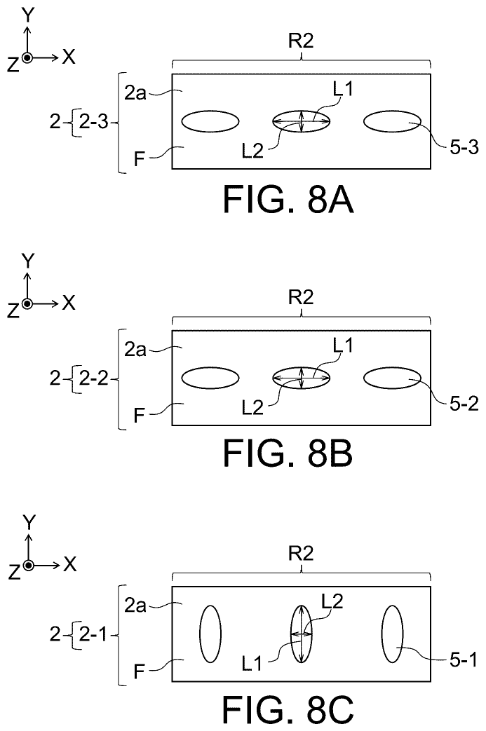

Similarly to the semiconductor device of the first embodiment, the semiconductor device of the present comparative example has the structure illustrated in FIGS. 1 to 6. However, the semiconductor device of the first embodiment has a structure illustrated in FIGS. 8A to 8C to be described later, but the semiconductor device of the present comparative example has a structure illustrated in FIGS. 7A, 7B, and 7C.

FIGS. 7A, 7B and 7C illustrate three pillar portions 5 in the stacked film 2 (staircase portion R2) of the present comparative example. FIG. 7A illustrates a planar shape (XY sectional shape) of the upper partial pillar portion 5-3 in each pillar portion 5, FIG. 7B illustrates the planar shape of the intermediate pillar portion 5-2 in each pillar portion 5, and FIG. 7C illustrates a planar shape of the lower partial pillar portion 5-1 in each pillar portion 5.

As illustrated in FIG. 7A, each upper partial pillar portion 5-3 of the present comparative example has an elliptical shape in a plan view. FIG. 7A illustrates a major radius L1 and a minor radius L2 of this ellipse (L1>L2). In each upper partial pillar portion 5-3 of the present comparative example, the major radius L1 is parallel to the X direction, and accordingly, the angle of the major radius L1 relative to the X direction is 0°. In each upper partial pillar portion 5-3 of the present comparative example, the minor radius L2 is orthogonal to the X direction, and accordingly, the angle of the minor radius L2 relative to the X direction is 90°. As a result, in each upper partial pillar portion 5-3 of the present comparative example, the angle of the major radius L1 relative to the X direction is smaller than the angle of the minor radius L2 relative to the X direction.

This is the same in each intermediate pillar portion 5-2 of the present comparative example. As illustrated in FIG. 7B, each intermediate pillar portion 5-2 of the present comparative example has an elliptical shape in a plan view. This ellipse as well has the major radius L1 and the minor radius L2 described above. In each intermediate pillar portion 5-2 of the present comparative example, the major radius L1 is parallel to the X direction, and the minor radius L2 is orthogonal to the X direction.

This is the same in each lower partial pillar portion 5-1 of the present comparative example. As illustrated in FIG. 7C, each lower partial pillar portion 5-1 of the present comparative example has an elliptical shape in a plan view. This ellipse as well has the major radius L1 and the minor radius L2 described above. In each lower partial pillar portion 5-1 of the present comparative example, the major radius L1 is parallel to the X direction, and the minor radius L2 is orthogonal to the X direction.

Note that, in the present specification, the term “major radius L1” is used as a term representing a line segment denoted by reference sign “L1” and a term representing the length of the line segment denoted by reference sign “L1”. Similarly, in the present specification, the term “minor radius L2” is used as a term representing a line segment denoted by reference sign “L2” and a term representing the length of the line segment denoted by reference sign “L2”. For example, the sentence “the angle of the major radius L1 relative to the X direction is smaller than the angle of the minor radius L2 relative to the X direction.”, the terms “major radius L1” and “minor radius L2” are used as terms representing line segments. The major radius L1 and the minor radius L2 in this meaning are also referred to as a long axis and a short axis, respectively. In the sentence “FIG. 7A illustrates a major radius L1 and a minor radius L2 of this ellipse (L1>L2).”, the terms “major radius L1” and “minor radius L2” are used as terms representing the lengths of line segments. The major radius L1 and the minor radius L2 in this meaning are also expressed as “the length of the long axis” and “the length of the short axis”, respectively.

FIGS. 8A to 8C are plan views illustrating the structure of the semiconductor device of the first embodiment.

FIGS. 8A, 8B, and 8C illustrate three pillar portions 5 in the stacked film 2 (staircase portion R2) of the present embodiment. FIG. 8A illustrates a planar shape (XY sectional shape) of the upper partial pillar portion 5-3 in each pillar portion 5, FIG. 8B illustrates a planar shape of the intermediate pillar portion 5-2 in each pillar portion 5, and FIG. 8C illustrates a planar shape of the lower partial pillar portion 5-1 in each pillar portion 5.

As illustrated in FIG. 8A, each upper partial pillar portion 5-3 of the present embodiment has an elliptical shape in a plan view. FIG. 8A illustrates the major radius L1 and the minor radius L2 of this ellipse (L1>L2). In each upper partial pillar portion 5-3 of the present embodiment, the major radius L1 is parallel to the X direction, and accordingly, the angle of the major radius L1 relative to the X direction is 0°. In each upper partial pillar portion 5-3 of the present embodiment, the minor radius L2 is orthogonal to the X direction, and accordingly, the angle of the minor radius L2 relative to the X direction is 90°. As a result, in each upper partial pillar portion 5-3 of the present embodiment, the angle of the major radius L1 relative to the X direction is smaller than the angle of the minor radius L2 relative to the X direction. Each upper partial pillar portion 5-3 of the present embodiment is an example of a first partial pillar portion and an example of a third partial pillar portion. The major radius L1 and the minor radius L2 of each upper partial pillar portion 5-3 of the present embodiment are an example of a first major radius and a first minor radius and an example of a third major radius and a third minor radius.

This is the same in each intermediate pillar portion 5-2 of the present embodiment. As illustrated in FIG. 8B, each intermediate pillar portion 5-2 of the present embodiment has an elliptical shape in a plan view. This ellipse as well has the major radius L1 and the minor radius L2 described above. In each intermediate pillar portion 5-2 of the present embodiment, the major radius L1 is parallel to the X direction, and the minor radius L2 is orthogonal to the X direction. Each intermediate pillar portion 5-2 of the present embodiment as well is an example of the first partial pillar portion and an example of the third partial pillar portion. The major radius L1 and the minor radius L2 of each intermediate pillar portion 5-2 of the present embodiment as well are an example of the first major radius and the first minor radius and an example of the third major radius and the third minor radius.

As illustrated in FIG. 8C, each lower partial pillar portion 5-1 of the present embodiment has an elliptical shape in a plan view. This ellipse as well has the major radius L1 and the minor radius L2 described above. However, in each lower partial pillar portion 5-1 of the present embodiment, the major radius L1 is orthogonal to the X direction, and accordingly, the angle of the major radius L1 relative to the X direction is 90°. In each lower partial pillar portion 5-1 of the present embodiment, the minor radius L2 is parallel to the X direction, and accordingly, the angle of the minor radius L2 relative to the X direction is 0°. As a result, in each lower partial pillar portion 5-1 of the present embodiment, the angle of the major radius L1 relative to the X direction is larger than the angle of the minor radius L2 relative to the X direction. Each lower partial pillar portion 5-1 of the present embodiment is an example of a second partial pillar portion and an example of a fourth partial pillar portion. The major radius L1 and the minor radius L2 of each lower partial pillar portion 5-1 of the present embodiment are an example of a second major radius and a second minor radius are an example of a fourth major radius and a fourth minor radius.

In this manner, the planar shape of each upper partial pillar portion 5-3 of the present embodiment is an ellipse with the major radius L1 being parallel to the X direction and the minor radius L2 being orthogonal to the X direction as illustrated in FIG. 8A. Hereinafter, such a pillar portion is referred to as a “horizontal pillar”. The planar shape of each lower partial pillar portion 5-1 of the present embodiment is an ellipse with the major radius L1 being orthogonal to the X direction and the minor radius L2 being parallel to the X direction as illustrated in FIG. 8C. Hereinafter, such a pillar portion is referred to as a “vertical pillar”. Each pillar portion 5 of the present embodiment includes the upper partial pillar portion 5-3 that is a horizontal pillar, the intermediate pillar portion 5-2 that is a horizontal pillar, and the lower partial pillar portion 5-1 that is a vertical pillar.

In the present embodiment, the lower partial pillar portion 5-1, in other words, the lowest pillar portion in each pillar portion 5 is a vertical pillar. The upper partial pillar portion 5-3, in other words, the highest pillar portion in each pillar portion 5 is a horizontal pillar. The intermediate pillar portion 5-2, in other words, a pillar portion other than the lowest and highest pillar portions in each pillar portion 5 is a horizontal pillar.

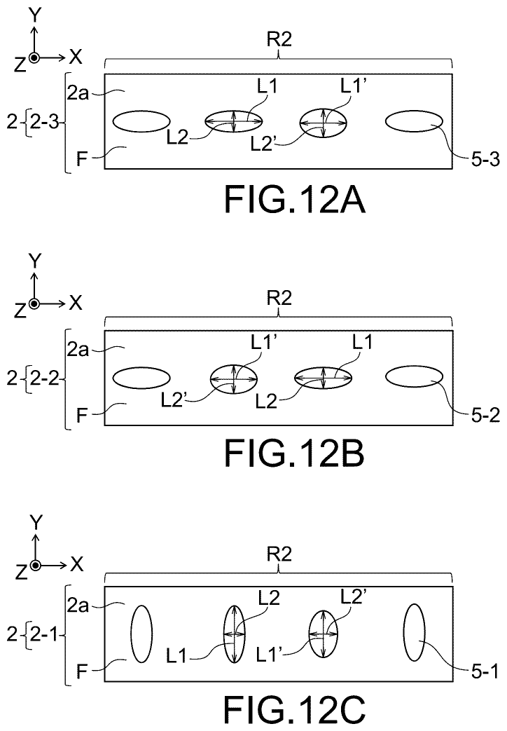

Note that, in each pillar portion 5 of the present embodiment, the major radius of the lower partial pillar portion 5-1, the major radius of the intermediate pillar portion 5-2, and the major radius of the upper partial pillar portion 5-3 may have the same value (L1) or different values. For example, these major radii may have different values in a case where bowing has occurred to the side face of a hole for each pillar portion 5 when the hole is formed. Alternatively, these major radii may be intentionally set to different values as illustrated in FIGS. 12A to 12C to be described later or the like. Similarly, in each pillar portion 5 of the present embodiment, the minor radius of the lower partial pillar portion 5-1, the minor radius of the intermediate pillar portion 5-2, and the minor radius of the upper partial pillar portion 5-3 may have the same value (L2) or different values.

The planar shape of each lower partial pillar portion 5-1 of the present embodiment does not necessarily need to be an ellipse that is mathematically rigorous and may be a figure (for example, an egg shape or an elongated oval) that is recognizable as an ellipse. Moreover, the planar shape of each lower partial pillar portion 5-1 of the present embodiment may be any other figure having a dimension that is recognizable as the major radius L1 and a dimension that is recognizable as the minor radius L2. Such a figure is, for example, a rhombus or a rectangle. In the case of a rhombus, the lengths of the two diagonal lines of the rhombus are recognizable as the major radius L1 and the minor radius L2. In the case of a rectangle, the lengths of the long and short sides of the rectangle are recognizable as the major radius L1 and the minor radius L2. Accordingly, the planar shape of each lower partial pillar portion 5-1 of the present embodiment may be, for example, a figure close to a rhombus or a figure close to a rectangle.

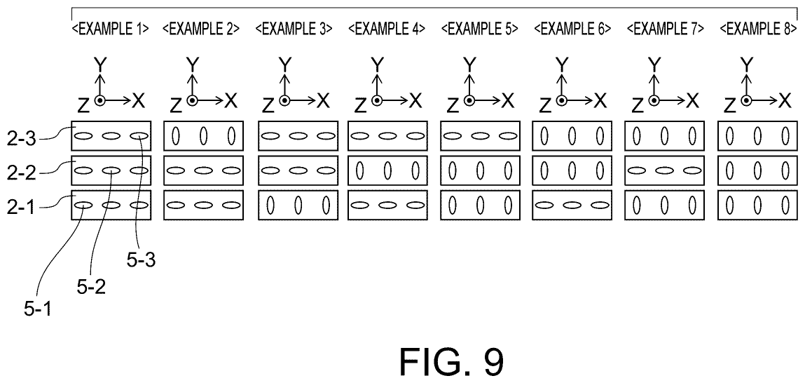

FIG. 9 is a plan view illustrating Examples 1 to 8 of the structure of the semiconductor device of the first embodiment.

In Example 1, each pillar portion 5 includes the upper partial pillar portion 5-3 that is a horizontal pillar, the intermediate pillar portion 5-2 that is a horizontal pillar, and the lower partial pillar portion 5-1 that is a horizontal pillar. Accordingly, each pillar portion 5 of Example 1 includes three horizontal pillars.

In Example 2, each pillar portion 5 includes the upper partial pillar portion 5-3 that is a vertical pillar, the intermediate pillar portion 5-2 that is a horizontal pillar, and the lower partial pillar portion 5-1 that is a horizontal pillar. In Example 3, each pillar portion 5 includes the upper partial pillar portion 5-3 that is a horizontal pillar, the intermediate pillar portion 5-2 that is a horizontal pillar, and the lower partial pillar portion 5-1 that is a vertical pillar. In Example 4, each pillar portion 5 includes the upper partial pillar portion 5-3 that is a horizontal pillar, the intermediate pillar portion 5-2 that is a vertical pillar, and the lower partial pillar portion 5-1 that is a horizontal pillar. Accordingly, each pillar portion 5 of Examples 2 and 4 includes two horizontal pillars and one vertical pillar.

In Example 5, each pillar portion 5 includes the upper partial pillar portion 5-3 that is a horizontal pillar, the intermediate pillar portion 5-2 that is a vertical pillar, and the lower partial pillar portion 5-1 that is a vertical pillar. In Example 6, each pillar portion 5 includes the upper partial pillar portion 5-3 that is a vertical pillar, the intermediate pillar portion 5-2 that is a vertical pillar, and the lower partial pillar portion 5-1 that is a horizontal pillar. In Example 7, each pillar portion 5 includes the upper partial pillar portion 5-3 that is a vertical pillar, the intermediate pillar portion 5-2 that is a horizontal pillar, and the lower partial pillar portion 5-1 that is a vertical pillar. Accordingly, each pillar portion 5 of Examples 5 to 7 includes one horizontal pillar and two vertical pillars.

In Example 8, each pillar portion 5 includes the upper partial pillar portion 5-3 that is a vertical pillar, the intermediate pillar portion 5-2 that is a vertical pillar, and the lower partial pillar portion 5-1 that is a vertical pillar. Accordingly, each pillar portion 5 of Example 8 includes three vertical pillars.

A displacement amount of each finger portion F will be described below. The displacement amount of each finger portion F is the Y-coordinate difference between the lower and upper ends of the finger portion F. As the displacement amount of each finger portion F increases, the tilt of the finger portion F in the Y direction increases. Accordingly, as the displacement amount of each finger portion F increases, the finger portion F is more likely to collapse in the Y direction.

The displacement amounts of Examples 1 to 3 were compared to determine influence of a vertical pillar on the displacement amount of each finger portion F. As a result of the comparison, it was found that the displacement amount of Example 2 is smaller than the displacement amount of Example 1, and the displacement amount of Example 3 is smaller than the displacement amount of Example 2 (Example 1>Example 2>Example 3). According to this result, the displacement amount of a finger portion F including a vertical pillar is smaller than the displacement amount of a finger portion F including no vertical pillar. This is thought to be because a vertical pillar, which extends in the Y direction, is more likely to prevent the displacement amount of the corresponding finger portion F from increasing in the Y direction.

Thus, the pillar portions 5 of the present embodiment illustrated in FIGS. 8A to 8C each include a vertical pillar (the lower partial pillar portion 5-1). This makes it possible to effectively prevent tilt and collapse of the finger portions F as compared to the pillar portions 5 of the comparative example illustrated in FIGS. 7A to 7C.

Each pillar portion 5 illustrated in FIGS. 8A to 8C includes the lower partial pillar portion 5-1 that is a vertical pillar as in Example 3. This is because, according to the results of Examples 2 and 3, the displacement amount of a finger portion F including a vertical pillar at a low position is smaller than the displacement amount of a finger portion F including a vertical pillar at a high position. This makes it possible to effectively prevent tilt and collapse of each finger portion F as compared to Example 2.

Each pillar portion 5 illustrated in FIGS. 8A to 8C may further include the upper partial pillar portion 5-3 or intermediate pillar portion 5-2 that is a vertical pillar as in Example 5 or 7. Alternatively, each pillar portion 5 in FIGS. 8A to 8C may further include the upper partial pillar portion 5-3 and the intermediate pillar portion 5-2 that are vertical pillars as in Example 8. However, a horizontal pillar has an effect of preventing failure of word lines (the electrode layers 2b) in the corresponding finger portion F. Thus, each pillar portion 5 of the present embodiment preferably includes one vertical pillar and two horizontal pillars or includes two vertical pillars and one horizontal pillar.

### (1) First Modification

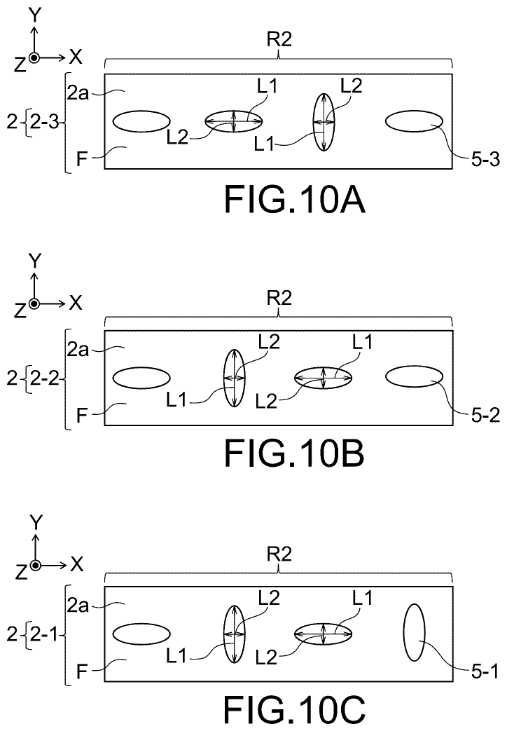

FIGS. 10A to 10C are cross-sectional views illustrating the structure of a semiconductor device of a first modification of the first embodiment.

FIGS. 10A, 10B, and 10C illustrate four pillar portions 5 in the stacked film 2 (staircase portion R2) of the present modification. FIGS. 10A to 10C correspond to FIGS. 8A to 8C, respectively.

Hereinafter, the number of vertical pillars and the number of horizontal pillars in each pillar portion 5 are represented by Na and Nb, respectively. The semiconductor device of the present modification includes not only pillar portions 5 with Na=1 and Nb=2 but also pillar portions 5 with Na≠1 and Nb≠2. For example, FIGS. 10A to 10C illustrate two pillar portions 5 with Na=1 and Nb=2, one pillar portion 5 with Na=2 and Nb=1, and one pillar portion 5 with Na=0 and Nb=3. The two pillar portions 5 with Na=1 and Nb=2 include a pillar portion 5 including the lower partial pillar portion 5-1 that is a vertical pillar, and a pillar portion 5 including the upper partial pillar portion 5-3 that is a vertical pillar. In this manner, the semiconductor device of the present modification may include various kinds of pillar portions 5.

However, in a case where K represents the total number of pillar portions 5 in the semiconductor device of the present modification, a total number K1 of “lower partial pillar portions 5-1 that are vertical pillars” in the semiconductor device of the present modification is preferably larger than 50% of K (K1>0.5K). This makes it possible to obtain the same effect as in Example 3.

In this case, a total number K2 of “intermediate pillar portions 5-2 that are vertical pillars” in the semiconductor device of the present modification or a total number K3 of “upper partial pillar portions 5-3 that are vertical pillars” in the semiconductor device of the present modification is preferably larger than 50% of K (K2>0.5K or K3>0.5K). This makes it possible to obtain the same effect as in Example 5 or 7.

Note that the condition of K1>0.5K is preferably satisfied for each finger portion F of the present modification. Specifically, in a case where k represents the total number of pillar portions 5 in each finger portion F of the present modification, a total number k1 of “lower partial pillar portions 5-1 that are vertical pillars” in each finger portion F of the present modification is preferably larger than 50% of k (k1>0.5k).

In this case, the total number K2 of “intermediate pillar portions 5-2 that are vertical pillars” in each finger portion F of the present modification or the total number K3 of “upper partial pillar portions 5-3 that are vertical pillars” in each finger portion F of the present modification is preferably larger than 50% of k (k2>0.5k or k3>0.5k).

### (2) Second Modification

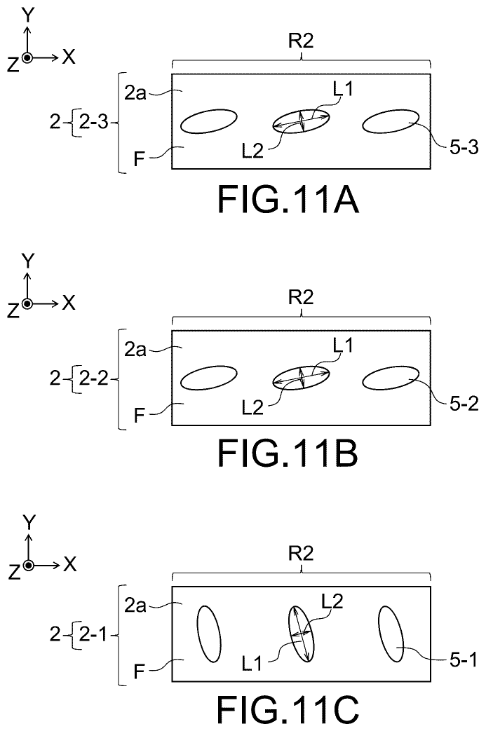

FIGS. 11A to 11C are cross-sectional views illustrating the structure of a semiconductor device of a second modification of the first embodiment.

FIGS. 11A, 11B, and 11C illustrate three pillar portions 5 in the stacked film 2 (staircase portion R2) of the present modification. FIGS. 11A to 11C correspond to FIGS. 8A to 8C, respectively.

Each lower partial pillar portion 5-1 of the present modification has a shape similar to that of a vertical pillar. Specifically, the major radius L1 of each lower partial pillar portion 5-1 is not orthogonal to the X direction and the minor radius L2 thereof is not parallel to the X direction, but the angle of the major radius L1 relative to the X direction is larger than the angle of the minor radius L2 relative to the X direction (FIG. 11C).

Moreover, each intermediate pillar portion 5-2 of the present modification has a shape similar to that of a horizontal pillar. Specifically, the major radius L1 of each intermediate pillar portion 5-2 is not parallel to the X direction and the minor radius L2 thereof is not orthogonal to the X direction, but the angle of the major radius L1 relative to the X direction is smaller than the angle of the minor radius L2 relative to the X direction (FIG. 11B).

Similarly, each upper partial pillar portion 5-3 of the present modification has a shape similar to a horizontal pillar. Specifically, the major radius L1 of each upper partial pillar portion 5-3 is not parallel to the X direction and the minor radius L2 thereof is not orthogonal to the X direction, but the angle of the major radius L1 relative to the X direction is smaller than the angle of the minor radius L2 relative to the X direction (FIG. 11A).

The present modification makes it possible to obtain the same effect as in Example 3. Note that, in FIG. 11C, the angle of the major radius L1 relative to the X direction and the angle of the minor radius L2 relative to the X direction may be different for each individual lower partial pillar portion 5-1. This is the same for FIGS. 11B and 11A.

### (3) Third Modification

FIGS. 12A to 12C are cross-sectional views illustrating the structure of a semiconductor device of a third modification of the first embodiment.

FIGS. 12A, 12B, and 12C illustrate four pillar portions 5 in the stacked film 2 (staircase portion R2) of the present modification. FIGS. 12A to 12C correspond to FIGS. 8A to 8C, respectively.

In the present modification, the lower partial pillar portions 5-1, the intermediate pillar portions 5-2, and the upper partial pillar portions 5-3 of these pillar portions 5 include not only pillar portions with the major radius L1 and the minor radius L2 but also pillar portions with a major radius L1′ and a minor radius L2′. In the present modification, the length of the major radius L1′ is different from the length of the major radius L1 (L1′≠L1), and the length of the minor radius L2′ is different from the length of the minor radius L2 (L2′≠L2). However, in the present modification, the length of the major radius L1′ may be equal to the length of the major radius L1 (L1′=L1), or the length of the minor radius L2′ may be equal to the length of the minor radius L2 (L2′=L2). FIGS. 12A to 12C exemplarily illustrate three lower partial pillar portions 5-1, three intermediate pillar portions 5-2, and three upper partial pillar portions 5-3 with the major radius L1 and the minor radius L2, and one lower partial pillar portion 5-1, one intermediate pillar portion 5-2, and one upper partial pillar portion 5-3 with the major radius L1′ and the minor radius L2′.

In FIG. 12A, the major radius L1 (or L1′) of each upper partial pillar portion 5-3 is parallel to the X direction, and the minor radius L2 (or L2′) of each upper partial pillar portion 5-3 is orthogonal to the X direction. In FIG. 12B, the major radius L1 (or L1′) of each intermediate pillar portion 5-2 is parallel to the X direction, and the minor radius L2 (or L2′) of each intermediate pillar portion 5-2 is orthogonal to the X direction. In FIG. 12C, the major radius L1 (or L1′) of each lower partial pillar portion 5-1 is orthogonal to the X direction, and the minor radius L2 (or L2′) of each lower partial pillar portion 5-1 is parallel to the X direction. Accordingly, each pillar portion 5 of the present modification includes the lower partial pillar portion 5-1 that is a vertical pillar, the intermediate pillar portion 5-2 that is a horizontal pillar, and the upper partial pillar portion 5-3 that is a horizontal pillar.

The present modification makes it possible to obtain the same effect as in Example 3. Note that the semiconductor device of the present modification includes lower partial pillar portions 5-1, intermediate pillar portions 5-2, and upper partial pillar portions 5-3 with two kinds of major radii (L1 and L1′) and minor radii (L2 and L2′), but instead, may include lower partial pillar portions 5-1, intermediate pillar portions 5-2, and upper partial pillar portions 5-3 with three or more kinds of major radii and minor radii.

As described above, each pillar portion 5 of the present embodiment includes one or more vertical pillars and one or more horizontal pillars, and for example, includes the lower partial pillar portion 5-1 that is a vertical pillar, the intermediate pillar portion 5-2 that is a horizontal pillar, and the upper partial pillar portion 5-3 that is a horizontal pillar. Thus, the present embodiment makes it possible to excellently divide the stacked film 2 into a plurality of finger portions F. For example, by forming pillar portions 5 including vertical pillars, the present embodiment makes it possible to prevent the finger portions F from tilting or collapsing due to the staircase portion R2 in the stacked film 2 or the like.

Note that the above-described first to third modifications are applicable not only to the first embodiment but also to a second embodiment to be described later.

### Second Embodiment

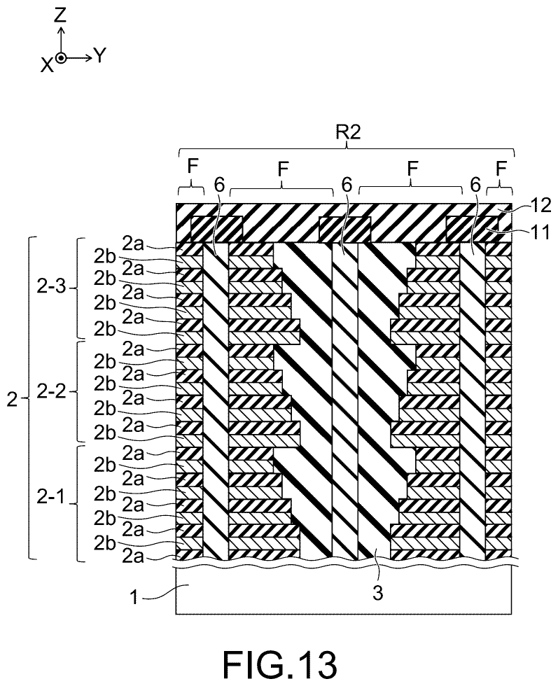

FIG. 13 is a cross-sectional view illustrating the structure of a semiconductor device of the second embodiment.

Similarly to FIGS. 5 and 6, FIG. 13 illustrates a YZ section of the semiconductor device of the present embodiment and specifically illustrates a YZ section of the stacked film 2 (staircase portion R2) of the present embodiment. The semiconductor device of the present embodiment includes the same constituent components as the semiconductor device of the first embodiment. However, the semiconductor device of the present embodiment includes a plurality of bridging portions 11 formed on the plurality of insulators 6 and covered by the inter layer dielectric 12.

Each bridging portion 11 is formed on the corresponding one insulator 6. In FIG. 13, each bridging portion 11 is continuously formed on the upper face of the insulator 6, the upper face of a finger portion F (or the inter layer dielectric 3) in the +Y direction relative to the insulator 6, and the upper face of a finger portion F (or the inter layer dielectric 3) in the-Y direction relative to the insulator 6. Accordingly, the bridging portion 11 bridges the finger portion F (or the inter layer dielectric 3) in the +Y direction relative to the insulator 6 and the finger portion F (or the inter layer dielectric 3) in the-Y direction relative to the insulator 6. The bridging portions 11 of the present embodiment are provided to prevent deformation of the finger portions F, for example. FIG. 13 illustrates three bridging portions 11 formed on the upper faces of three insulators 6, respectively.

Each bridging portion 11 is, for example, an insulator, and examples of the insulator include an SiO₂ film and an insulating metal compound film such as a metal oxide film. Meanwhile, the inter layer dielectric 12 is, for example, a TEOS film or an SiO₂ film.

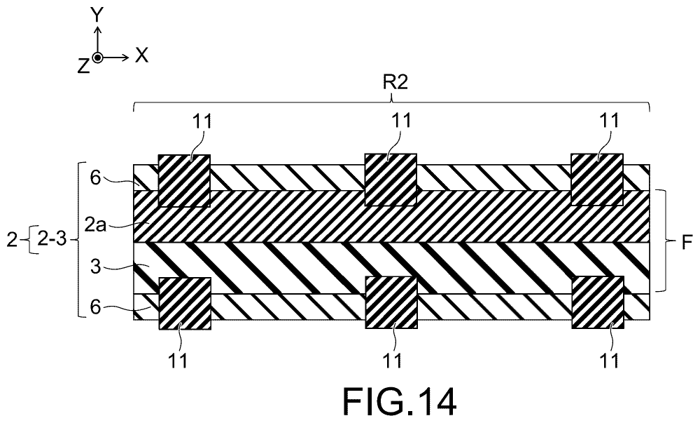

FIG. 14 is a plan view illustrating the structure of the semiconductor device of the second embodiment.

FIG. 14 illustrates one of the four finger portions F illustrated in FIG. 13 and two of the three insulators 6 illustrated in FIG. 13. FIG. 14 also illustrates a plurality of bridging portions 11 formed on each insulator 6. In FIG. 14, three bridging portions 11 are disposed on each insulator 6.

Note that the semiconductor device of the present embodiment may include not only a plurality of bridging portions 11 on each insulator 6 in the staircase portion R2 but also a plurality of bridging portions 11 on each insulator 6 in the non-staircase portion R1.

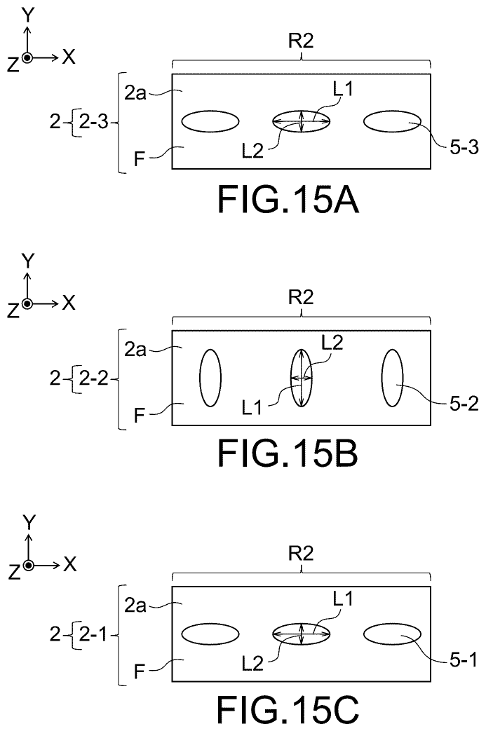

FIGS. 15A to 15C is a plan view illustrating the structure of the semiconductor device of the second embodiment.

FIGS. 15A, 15B, and 15C illustrate three pillar portions 5 in the stacked film 2 (staircase portion R2) of the present embodiment. FIG. 15A illustrates a planar shape (XY sectional shape) of the upper partial pillar portion 5-3 in each pillar portion 5, FIG. 15B illustrates a planar shape of the intermediate pillar portion 5-2 in each pillar portion 5, and FIG. 15C illustrates a planar shape of the lower partial pillar portion 5-1 in each pillar portion 5.

FIGS. 15A to 15C correspond to FIGS. 8A to 8C, respectively. As illustrated in FIGS. 8A to 8C, each pillar portion 5 of the first embodiment includes the upper partial pillar portion 5-3 that is a horizontal pillar, the intermediate pillar portion 5-2 that is a horizontal pillar, and the lower partial pillar portion 5-1 that is a vertical pillar. However, as illustrated in FIGS. 15A to 15C, each pillar portion 5 of the present embodiment includes the upper partial pillar portion 5-3 that is a horizontal pillar, the intermediate pillar portion 5-2 that is a vertical pillar, and the lower partial pillar portion 5-1 that is a horizontal pillar.

Note that each pillar portion 5 of the present embodiment may include the upper partial pillar portion 5-3 that is a vertical pillar, the intermediate pillar portion 5-2 that is a horizontal pillar, and the lower partial pillar portion 5-1 that is a horizontal pillar. In other words, in each pillar portion 5 of the present embodiment, the pillar portions other than the lowest pillar portion may be vertical pillars.

Subsequently, Examples 1 to 8 of the structure of the semiconductor device of the present embodiment will be described below with reference to FIG. 9 again.

Examples 1 to 8 illustrated in FIG. 9 are common to the first embodiment and the present embodiment. However, influence of a vertical pillar on the displacement amount of each finger portion F is different between Examples 1 to 8 in the first embodiment and Examples 1 to 8 in the present embodiment. Hereinafter, Examples 1 to 8 in the present embodiment will be described.

The displacement amounts of Examples 1 to 3 were compared to determine influence of a vertical pillar on the displacement amount of each finger portion F. As a result of the comparison, it was found that the displacement amount of Example 3 is substantially equal to the displacement amount of Example 1, and the displacement amount of Example 2 is smaller than the displacement amount of Example 1 and the displacement amount of Example 3 (Example 1≈Example 3>Example 2). According to this result, the displacement amount of a finger portion F including a vertical pillar at a high position is smaller than the displacement amount of a finger portion F including no vertical pillar and the displacement amount of a finger portion F including a vertical pillar at a low position.

Although the semiconductor device of the first embodiment includes no bridging portions 11 on each insulator 6 (FIG. 6), the semiconductor device of the present embodiment includes bridging portions 11 on each insulator 6 (FIG. 13). Accordingly, in each finger portion F of the first embodiment, the position of its lower end is less likely to change in the Y direction whereas the position of its upper end is likely to change in the Y direction, but in each finger portion F of the present embodiment, the positions of its lower and upper ends are less likely to change in the Y direction. In each finger portion F of the present embodiment, the positions of portions near its upper end, in other words, the positions of portions in the upper partial stacked film 2-3 and the intermediate stacked film 2-2 are likely to change in the Y direction. This is thought to be the reason why, in the present embodiment, the displacement amount of a finger portion F including a vertical pillar at a high position is smaller than the displacement amount of a finger portion F including no vertical pillar and the displacement amount of a finger portion F including a vertical pillar at a low position.

Thus, each pillar portion 5 of the present embodiment preferably includes the upper partial pillar portion 5-3 or intermediate pillar portion 5-2 that is a vertical pillar as described above with reference to FIGS. 15A to 15C. Such a configuration is exemplarily illustrated in Example 2 or 4 or the like. This makes it possible to effectively prevent tilt and collapse of each finger portion F of the present embodiment.

Each pillar portion 5 of the present embodiment may include the upper partial pillar portion 5-3 and the intermediate pillar portion 5-2 that are vertical pillars. Such a configuration is exemplarily illustrated in Example 6 or the like. Alternatively, each pillar portion 5 of the present embodiment may include the upper partial pillar portion 5-3, the intermediate pillar portion 5-2, and the lower partial pillar portion 5-1 that are vertical pillars. However, a horizontal pillar has an effect of preventing failure of word lines (the electrode layers 2b) in the corresponding finger portion F. Thus, each pillar portion 5 of the present embodiment preferably includes one vertical pillar and two horizontal pillars or includes two vertical pillars and one horizontal pillar.

As a result, it is preferable based on consideration of Examples 2, 4, and 6 that, in each pillar portion 5 of the present embodiment, the lower partial pillar portion 5-1 is a horizontal pillar and at least one of the intermediate pillar portion 5-2 and the upper partial pillar portion 5-3 is a vertical pillar.

Similarly to the first embodiment, the present embodiment makes it possible to excellently divide the stacked film 2 into a plurality of finger portions F.

Note that, in a case where the semiconductor device of the first or second embodiment is manufactured by bonding the substrate 1 and another substrate, the semiconductor device after completion does not necessarily need to include the substrate 1. An example of such a semiconductor device will be described below in a third embodiment.

### Third Embodiment

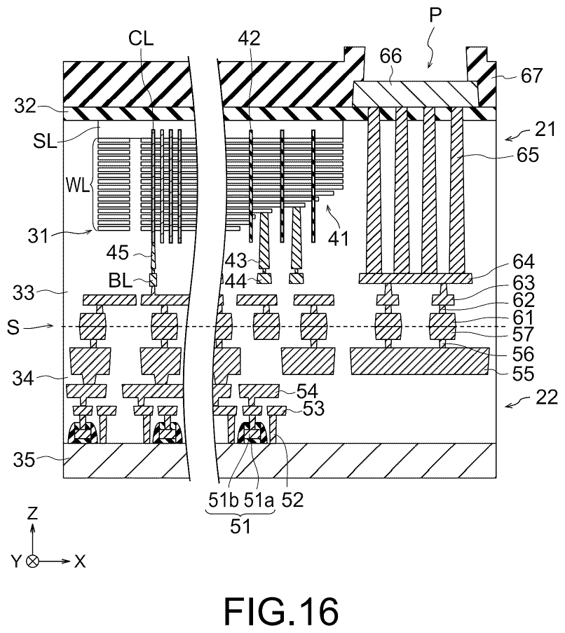

FIG. 16 is a cross-sectional view illustrating the structure of a semiconductor device of the third embodiment. The semiconductor device of the present embodiment is, for example, a three-dimensional semiconductor memory.

The semiconductor device of the present embodiment includes an array chip 21 and a circuit chip 22 that are bonded to each other. As described later, the semiconductor device of the present embodiment is manufactured by bonding an array wafer including the array chip 21 and a circuit wafer including the circuit chip 22.

The array chip 21 includes a memory cell array 31 including a plurality of memory cells, an insulator 32 on the memory cell array 31, and an inter layer dielectric 33 below the memory cell array 31. The insulator 32 is, for example, an SiO₂ film. The inter layer dielectric 33 is, for example, a stacked film including an SiO₂ film and other insulators. A portion of the memory cell array 31 of the present embodiment corresponds to the stacked film 2 of the first or second embodiment.

The circuit chip 22 is provided below the array chip 21. Reference sign S denotes a bonding face between the array chip 21 and the circuit chip 22. The circuit chip 22 includes an inter layer dielectric 34 below the inter layer dielectric 33, and a substrate 35 below the inter layer dielectric 34. The inter layer dielectric 34 is, for example, a stacked film including an SiO₂ film and other insulators. The substrate 35 is, for example, a semiconductor substrate such as an Si substrate.

FIG. 16 illustrates an X direction and a Y direction parallel to the surface of the substrate 35 and orthogonal to each other, and a Z direction orthogonal to the surface of the substrate 35. The X direction, the Y direction, and the Z direction intersect one another. In the present embodiment, as in the first and second embodiments, the +Z direction is an upward direction, and the-Z direction is a downward direction. The −Z direction may or may not be aligned with the direction of gravity.

The array chip 21 includes a plurality of word lines WL as a plurality of electrode layers in the memory cell array 31. FIG. 16 illustrates a staircase structure portion 41 in the memory cell array 31, and a plurality of pillar portions 42 provided in the staircase structure portion 41. Each word line WL extends in the X direction and is electrically connected to a word line layer 44 through a contact plug 43. Each columnar portion CL penetrating through the above-described plurality of word lines WL is electrically connected to a bit line BL through a via plug 45 and electrically connected to a source line SL. The bit line BL extends in the Y direction and is provided below the above-described plurality of word lines WL. The source line SL extends in the X direction and is provided above the above-described plurality of word lines WL. The staircase structure portion 41, the pillar portions 42, the columnar portions CL, and the word lines WL of the present embodiment correspond to the staircase portion R2, the pillar portions 5, the columnar portions 4, and the electrode layers 2b of the first or second embodiment, respectively.

The circuit chip 22 includes a plurality of transistors 51. Each transistor 51 includes a gate insulator 51a and a gate electrode 51b that are sequentially provided on the substrate 35, and a non-illustrated source diffusion layer and a d non-illustrated drain diffusion layer that are provided in the substrate 35. The circuit chip 22 also includes a plurality of contact plugs 52 each provided on the gate electrode 51b, the source diffusion layer, or the drain diffusion layer of the corresponding one of the above-described plurality of transistors 51. The circuit chip 22 also includes an interconnect layer 53, an interconnect layer 54, and an interconnect layer 55. The interconnect layer 53 includes a plurality of interconnects and is provided on the above-described plurality of contact plugs 52. The interconnect layer 54 includes a plurality of interconnects and is provided on the interconnect layer 53. The interconnect layer 55 includes a plurality of interconnects and is provided on the interconnect layer 54.

The circuit chip 22 also includes a plurality of via plugs 56 provided on the interconnect layer 55, and a plurality of metal pads 57 provided on the plurality of via plugs 56. Each metal pad 57 is, for example, a metal layer including a copper (Cu) layer. The circuit chip 22 functions as a logic circuit that controls operation of the array chip 21. The logic circuit includes the transistors 51 and the like and is electrically connected to the metal pads 57.

The array chip 21 includes a plurality of metal pads 61 provided on the above-described plurality of metal pads 57, and a plurality of via plugs 62 provided on the plurality of metal pads 61. Each metal pad 61 is, for example, a metal layer including a Cu layer. The array chip 21 also includes an interconnect layer 63 and an interconnect layer 64. The interconnect layer 63 includes a plurality of interconnects and is provided on the above-described plurality of via plugs 62. The interconnect layer 64 includes a plurality of interconnects and is provided on the interconnect layer 63. The above-described bit line BL is included in the interconnect layer 64. The above-described logic circuit is electrically connected to the memory cell array 31 through the metal pads 61 and 57 and the like and controls operation of the memory cell array 31 through the metal pads 61 and 57 and the like.

The array chip 21 also includes a plurality of via plugs 65 provided on the interconnect layer 64, and a metal pad 66 provided on the plurality of via plugs 65 and the insulator 32. The array chip 21 also includes a passivation insulator 67 provided on the metal pad 66 and the insulator 32. The metal pad 66 is, for example, a metal layer including a Cu layer and functions as an external connection pad (bonding pad) of the semiconductor device of the present embodiment. The passivation insulator 67 is, for example, a stacked film including an SiO₂ film and an SiN film and has an opening P through which the upper face of the metal pad 66 is exposed. The metal pad 66 is electrically connectable to a mounting substrate or other devices through the opening P by a bonding wire, a soldering ball, a metal bump, or the like.

Note that, in the present embodiment, the plurality of insulators 6 (not illustrated) of the first or second embodiment extend in the X direction in the memory cell array 31. In the present embodiment, a plurality of bridging portions 11 (not illustrated) of the second embodiment may be formed below these insulators 6.

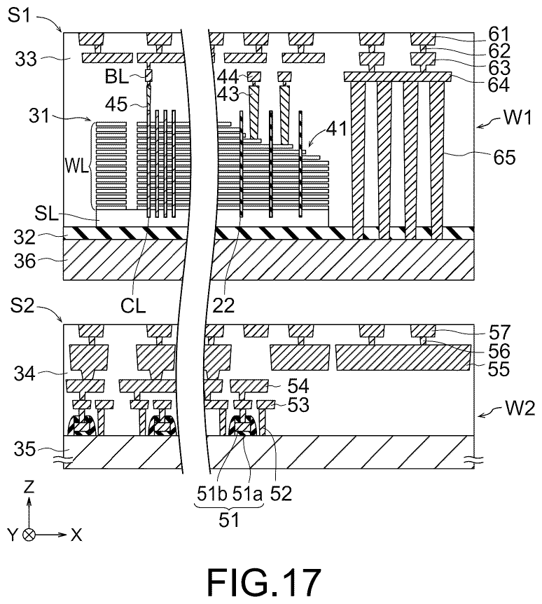

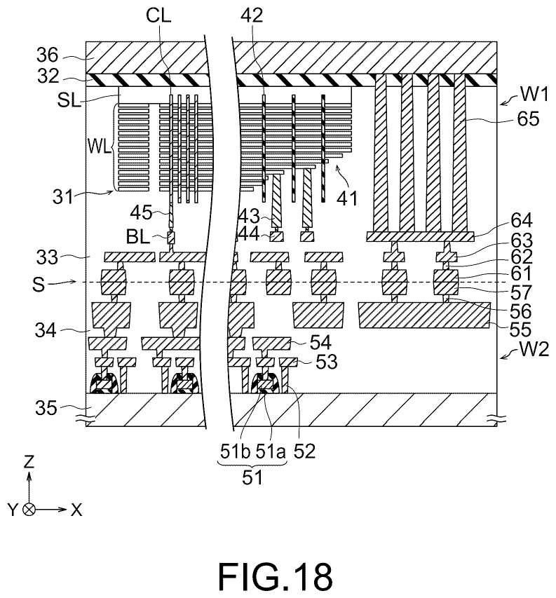

FIGS. 17 and 18 are cross-sectional views illustrating a method of manufacturing the semiconductor device of the third embodiment.

FIG. 17 illustrates an array wafer W1 including a plurality of array chips 21, and a circuit wafer W2 including a plurality of circuit chips 22. The orientation of the array wafer W1 in FIG. 17 is opposite the orientation of the array chip 21 in FIG. 16. In the present embodiment, a semiconductor device is manufactured by bonding the array wafer W1 and the circuit wafer W2. FIG. 17 illustrates the array wafer W1, the orientation of which is yet to be inverted for bonding, and FIG. 16 illustrates the array chip 21, the orientation of which is inverted for bonding and that is bonded and diced.

In FIG. 17, reference sign S1 denotes the upper face of the array wafer W1, and reference sign S2 denotes the upper face of the circuit wafer W2. The array wafer W1 includes a substrate 36 provided below the insulator 32. The substrate 36 is, for example, a semiconductor substrate such as an Si substrate. The substrate 36 of the present embodiment corresponds to the substrate 1 of the first or second embodiment.

In the present embodiment, first, as illustrated in FIG. 17, the memory cell array 31, the insulator 32, the inter layer dielectric 33, the metal pads 61, the via plugs 65, and the like are formed on the substrate 36 of the array wafer W1, and the inter layer dielectric 34, the transistors 51, the metal pads 57, and the like are formed on the substrate 35 of the circuit wafer W2. Subsequently, as illustrated in FIG. 18, the array wafer W1 and the circuit wafer W2 are bonded to each other by mechanical pressure such that the face S1 and the face S2 face each other. Accordingly, the inter layer dielectric 33 and the inter layer dielectric 34 are bonded to each other. Subsequently, the array wafer W1 and the circuit wafer W2 are annealed. Accordingly, the metal pads 61 and the metal pads 57 are joined together. In this manner, the substrate 36 and the substrate 35 are bonded to each other with the inter layer dielectrics 33 and 34 in between.

Thereafter, the substrate 36 is removed by chemical mechanical polishing (CMP) and the substrate 35 is thinned by CMP, and then, the array wafer W1 and the circuit wafer W2 are cut into a plurality of chips (dicing). In this manner, the semiconductor device illustrated in FIG. 16 is manufactured. Note that the metal pad 66 and the passivation insulator 67 are formed on the insulator 32 after the removal of the substrate 36 and the thinning of the substrate 35.

Note that although FIG. 16 illustrates the boundary face between the inter layer dielectric 33 and the inter layer dielectric 34 and the boundary face between the metal pads 61 and the metal pads 57, these boundary faces are typically not observed after the above-described annealing. However, the positions of the boundary faces can be estimated by detecting, for example, the tilt of the side face of both the metal pads 61 and the metal pads 57, and positional shift between the side face of the metal pads 61 and the side face of the metal pads 57.

The present embodiment makes it possible to apply the semiconductor device of the first or second embodiment and the manufacturing method thereof to the present embodiment.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a stacked film alternately including a plurality of first insulators and a plurality of electrode layers in a first direction, and including a non-staircase portion, and a staircase portion that is provided in a second direction relative to the non-staircase portion;
a first columnar portion including a charge storage layer and a semiconductor layer that are provided in the non-staircase portion; and
a first pillar portion including a second insulator that is provided in the staircase portion,
wherein
the stacked film includes a plurality of partial stacked films that are stacked in the first direction,
the first pillar portion includes a plurality of partial pillar portions that are respectively provided in the plurality of partial stacked films, and
the plurality of partial pillar portions in the first pillar portion include:
one or more first partial pillar portions each having a first major radius and a first minor radius in a plan view, an angle of the first major radius relative to the second direction being smaller than an angle of the first minor radius relative to the second direction; and
one or more second partial pillar portions each having a second major radius and a second minor radius in a plan view, an angle of the second major radius relative to the second direction being larger than an angle of the second minor radius relative to the second direction.

2. The device of claim 1, wherein the one or more second partial pillar portions include the lowest partial pillar portion among the plurality of partial pillar portions in the first pillar portion.

3. The device of claim 2, wherein the one or more first partial pillar portions include the highest partial pillar portion among the plurality of partial pillar portions in the first pillar portion.

4. The device of claim 2, wherein the one or more first partial pillar portions include a partial pillar portion other than the lowest and highest partial pillar portions among the plurality of partial pillar portions in the first pillar portion.

5. The device of claim 2, wherein
the stacked film includes a plurality of first plate portions that extend in the first direction and the second direction, and are adjacent to each other in a third direction,
the device further comprises a plurality of second plate portions that are provided in the stacked film, extend in the first direction and the second direction, and are alternately provided with the plurality of first plate portions in the third direction, and
no bridging portion is provided on an upper face of each of the plurality of second plate portions.

6. The device of claim 1, wherein the one or more first partial pillar portions include the lowest partial pillar portion among the plurality of partial pillar portions in the first pillar portion.

7. The device of claim 6, wherein the one or more second partial pillar portions include the highest partial pillar portion among the plurality of partial pillar portions in the first pillar portion.

8. The device of claim 6, wherein the one or more second partial pillar portions include a partial pillar portion other than the lowest and highest partial pillar portions among the plurality of partial pillar portions in the first pillar portion.

9. The device of claim 6, wherein
the stacked film includes a plurality of first plate portions that extend in the first direction and the second direction, and are adjacent to each other in a third direction,
the device further comprises a plurality of second plate portions that are provided in the stacked film, extend in the first direction and the second direction, and are alternately provided with the plurality of first plate portions in the third direction, and
the device further comprises a plurality of bridging portions that are respectively provided on upper faces of the plurality of second plate portions.

10. The device of claim 1, wherein the one or more first partial pillar portions each has the first major radius parallel to the second direction, and the first minor radius orthogonal to the second direction.

11. The device of claim 1, wherein the one or more second partial pillar portions each has the second major radius orthogonal to the second direction, and the second minor radius parallel to the second direction.

12. The device of claim 1, wherein a length of the first major radius is equal to a length of the second major radius.

13. The device of claim 1, wherein a length of the first minor radius is equal to a length of the second minor radius.

14. The device of claim 1, further comprising a second pillar portion including the second insulator that is provided in the staircase portion,
wherein
the second pillar portion includes a plurality of partial pillar portions that are respectively provided in the plurality of partial stacked films, and
the plurality of partial pillar portions in the second pillar portion include:
one or more third partial pillar portions each having a third major radius and a third minor radius in a plan view, an angle of the third major radius relative to the second direction being smaller than an angle of the third minor radius relative to the second direction, and
one or more fourth partial pillar portions each having a fourth major radius and a fourth minor radius in a plan view, an angle of the fourth major radius relative to the second direction being larger than an angle of the fourth minor radius relative to the second direction.

15. The device of claim 14, wherein
the one or more second partial pillar portions include the lowest partial pillar portion among the plurality of partial pillar portions in the first pillar portion, and
the one or more third partial pillar portions include the lowest partial pillar portion among the plurality of partial pillar portions in the second pillar portion.

16. The device of claim 15, wherein the one or more first partial pillar portions include the highest partial pillar portion among the plurality of partial pillar portions in the first pillar portion.

17. The device of claim 15, wherein the one or more first partial pillar portions include a partial pillar portion other than the lowest and highest partial pillar portions among the plurality of partial pillar portions in the first pillar portion.

18. The device of claim 15, wherein the one or more fourth partial pillar portions include the highest partial pillar portion among the plurality of partial pillar portions in the second pillar portion.

19. The device of claim 15, wherein the one or more fourth partial pillar portions include a partial pillar portion other than the lowest and highest partial pillar portions among the plurality of partial pillar portions in the second pillar portion.

20. The device of claim 14, wherein
a length of the first major radius is different from at least a length of any of the second major radius, the third major radius, and the fourth major radius, and/or
a length of the first minor radius is different from at least a length of any of the second minor radius, the third minor radius, and the fourth minor radius.
